(19) United States
(12) Patent Application Publication
(10) Pub. No.: US 2019/0011259 A1
(43) Pub. Date: Jan. 10, 2019

(54) MEMS DEVICE

(71) Applicant: RICHTEK TECHNOLOGY CORPORATION, Zhubei City (TW)

(72) Inventors: Chiung-Wen Lin, Changhua (TW); Chiung-Cheng Lo, Miaoli (TW)

(21) Appl. No.: 15/690,443

(22) Filed: Aug. 30, 2017

(30) Foreign Application Priority Data
Jul. 6, 2017 (CN) 201710546475.4

(51) Int. Cl. G01C 19/5621; B81B 3/00

(52) U.S. Cl. CPC G01C 19/5621; B81B 2201/0242; B81B 3/0027

(57) ABSTRACT

A MEMS device includes at least two masses and at least one spring assembly, each of the spring assemblies including at least two folded-shape springs and at least two connection portions. The folded-shape springs are directly connected to each other at a connection point, and the folded-shape springs are respectively connected to the masses through the corresponding connection portions, for operably driving the masses to move simultaneously inward or outward in a first direction.

### CROSS REFERENCE

The present invention claims priority to CN 201710546475.4, filed on Jul. 6, 2017.

### BACKGROUND OF THE INVENTION

### Field of Invention

The present invention relates to a MEMS (Micro-Electro-Mechanical System) device, in particular a MEMS device including two folded-shape springs for driving one or more mass structures in the MEMS device to move in opposite directions.

### Description of Related Art

MEMS devices including a tuning fork structure is one typical type of MEMS devices. The tuning fork includes a symmetric mass structure, wherein a pair of masses are coupled to vibrate in the same frequency. In the coupled vibration mode, the pair of masses move by the same amplitudes in opposite directions, so differential sensing is achieved to obtain a higher sensitivity.

FIG. 1A shows a prior art MEMS device 10 disclosed by U.S. Patent No. 2010/0186507, wherein the prior art MEMS device 10 includes two masses 11 and a rotation linkage 12. The rotation linkage 12 links the two masses 11 so that they move simultaneously inward or outward. The rotation linkage 12 is a long linkage structure, so the prior art MEMS device 10 needs a large motion space for the rotation linkage 12 to rotate. Besides, because the rotation linkage 12 has a long structure, it has a relatively large mass quantity and therefore, a significant portion of a driving force for driving the masses 11 is shared by the rotation linkage 12; hence, the required driving force is much higher. In addition, the rotation linkage 12 is located between the two masses 11, so the motion space occupied by the rotation linkage 12, which is large, is not available for accommodating other MEMS structures. A further drawback is that the rotation linkage 12 can only drive the masses 11 to move simultaneously inward or outward in one direction. However, when it is required to sense a multiple-direction motion, this prior art MEMS device 10 is incapable or the structure needs to be duplicated which will result in an even larger size.

FIG. 1B shows a MEMS design according to U.S. Pat. No. 9,127,943. It uses a combination of one single U-shape spring and two anchors to drive two masses Ma and Mb to move in opposite directions, for differential sensing. However, in operation, the motion of the mass Ma is partially coupled to the mass Mb (or the motion of the mass Mb is partially coupled to the mass Ma), such that the masses Ma and Mb will have a motion component which is in the same direction (“in-phase oscillation”), which could reduce the sensing sensitivity of the MEMS device with the differential driving or induce unwanted in-phase oscillation.

In view of the demerits of the prior art, the present invention provides a MEMS device capable of reducing the in-phase oscillation, and also capable of sensing a multiple-direction motion.

### SUMMARY OF THE INVENTION

In one perspective, the present invention provides a MEMS device, which includes: at least two masses; and at least one spring assembly, connected between the masses, each of the spring assemblies including: at least two folded-shape springs, directly connected to each other at a connection point; and at least two connection portions, wherein the folded-shape springs are respectively connected to the masses through the connection portions, for operably driving the masses to move oppositely in a first direction; for example, the masses move simultaneously inward or outward in the first direction.

In one embodiment, each of the spring assemblies is connected to a substrate through one anchor, and there is exactly one anchor between each spring assembly and the substrate.

In one embodiment, the connection point is connected to a compressional spring, for driving the connection point to move in a second direction which is perpendicular to the first direction, wherein the connection point and the compressional spring are directly or indirectly connected. In one embodiment, the connection point is connected to the compressional spring through a first internal mass.

In one embodiment, the MEMS device includes at least two spring assemblies, wherein the at least two masses are connected to each other through the at least two spring assemblies, and a layout of the at least two spring assemblies is mirror symmetric.

In one embodiment, at least one first internal mass is connected between the connection points of two spring assemblies, wherein the spring assemblies are configured to operably drive the at least one first internal mass to move in the second direction, or to operably drive the at least one first internal mass to rotate.

In one embodiment, the two connection points of the two spring assemblies are separated by a distance in the first direction, such that the connection points are configured to move in two separated trace lines which are parallel to the second direction and separated by the distance. The spring assemblies are configured to operably drive the at least one first internal mass to rotate.

In one embodiment, the MEMS device further includes at least two first internal masses, connected to each other through a compressional spring which is connected to one side of each of the first internal masses, and each of the first internal masses further includes another side connected to a corresponding one of the connection points, whereby the spring assemblies are configured to operably drive the at least two first internal mass to move oppositely in a second direction, which is perpendicular to the first direction.

In one embodiment, the MEMS device includes at least two first internal masses, one side of each of which is connected to the corresponding connection point, and another side of each of the first internal masses is connected to a corresponding anchor. A compressional spring is connected between the connection points. The spring assemblies are configured to operably drive the at least two first internal masses to rotate simultaneously in opposite directions.

In one embodiment, the at least two first internal masses are mirror-symmetrically located at opposite sides of the compressional spring, or are located at the same side of the compressional spring.

In one embodiment, the MEMS device includes two spring assemblies and at least one second internal mass. The at least one second internal mass is connected to the connection points, wherein the spring assemblies are configured to operably drive the at least one second internal mass to rotate.

In one embodiment, the MEMS device includes two second internal masses, wherein each of the second internal masses includes one side connected to a corresponding one of the connection portions, and another side connected to an anchor. The two spring assemblies are configured to operably drive the second internal masses to rotate simultaneously in opposite directions.

In one embodiment, the MEMS device includes two second internal masses, wherein each of the second internal masses includes one side connected to the corresponding connection portion, and another side connected to a same anchor. The two spring assemblies are configured to operably drive the second internal masses to rotate in opposite directions.

In one embodiment of the MEMS device, when the connection portions move simultaneously outward in the first direction, the connection point correspondingly moves outward in the second direction. Or, when the connection portions move simultaneously inward in the first direction, the connection point correspondingly moves inward in the second direction.

In one embodiment, each of the folded-shape springs includes a first side arm and a second side arm, which are respectively connected to the connection point and the connection portion. The first side arm and the second side arm are connected to each other (1) directly; (2) by a straight linear portion between the first side arm and the second side arm; (3) by an arc portion between the first side arm and the second side arm; or (by) a folded portion between the first side arm and the second side arm.

In one embodiment, the first side arm and the second side arm are respectively connected to the connection point and the connection portion, wherein an angle between the second side arm and the corresponding connection portion nearest to this second side arm is between 0 and 90 degrees. In one embodiment, when the spring assemblies drive the masses to move outward in the first direction, the angle increases. Or, when the spring assemblies drive the masses to move inward in the first direction, the angle decreases.

In one embodiment, the MEMS device includes a tuning fork MEMS structure. In one embodiment, the MEMS device includes a tuning fork gyroscope.

In one embodiment, the folded-shape springs of the spring assembly are connected to the at least two masses through the corresponding connection portions. The connection points are directly or indirectly connected to the compressional spring, wherein the connection points are connected to the anchor and the substrate through the compressional spring. Or, the connection points are connected to the first internal mass. The connection between the connection points and the compressional spring, or the connection between the connection points and the first internal mass, is to prevent the at least two masses from an in-phase motion in the first direction.

The objectives, technical details, features, and effects of the present invention will be better understood with regard to the detailed description of the embodiments below, with reference to the drawings.

### BRIEF DESCRIPTION OF THE DRAWINGS

FIGS. 1A and 1B respectively show two prior art MEMS devices.

FIGS. 2 and 3 show different motion statuses of a MEMS device according to one embodiment of the present invention.

FIGS. 4, 5, 6, 7, 8, and 9 show several embodiments of the connections between the spring assembly and the compressional spring according to the present invention.

FIGS. 10, 11, 12, 13, and 14 show several embodiments of the MEMS devices according the present invention.

FIGS. 15A, 15B, and 15C show several embodiments of folded-shape springs according to the present invention.

FIG. 16 shows an angle between a second side arm and a corresponding connection portion, according to one embodiment of the present invention.

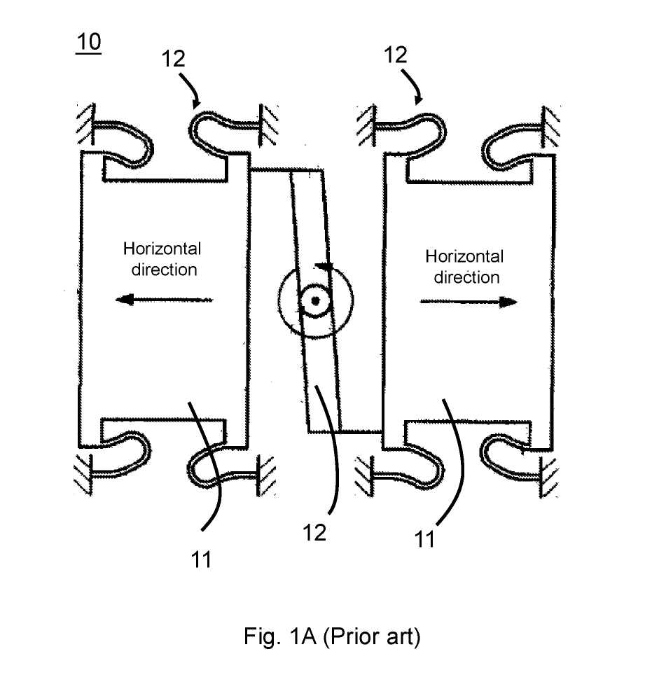

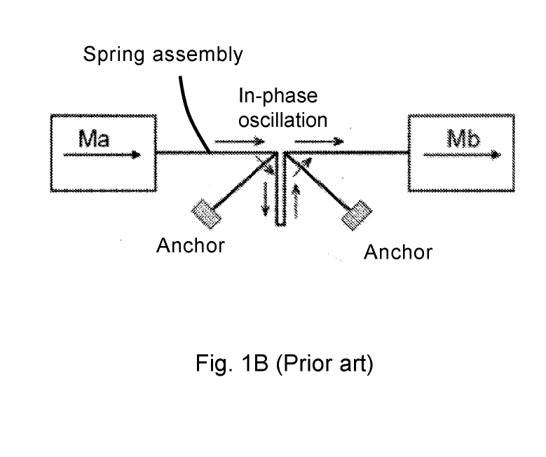

### DESCRIPTION OF THE PREFERRED EMBODIMENTS

The drawings as referred to throughout the description of the present invention are for illustrative purpose only, to show the interrelations between the components, but not drawn according to actual scale.

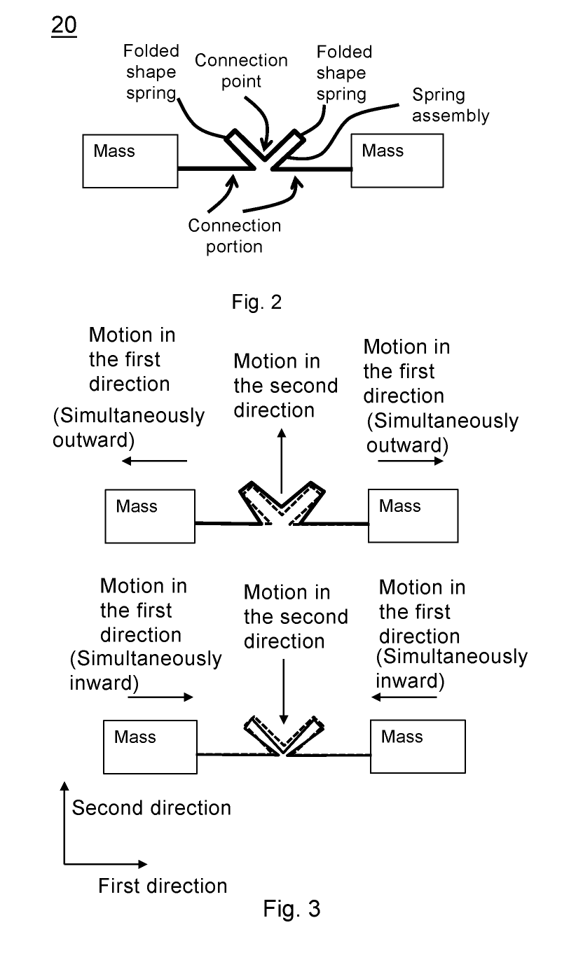

FIGS. 2 and 3 show different motion statuses of a MEMS device 20 according to one embodiment of the present invention. The MEMS device 20 includes: at least two masses, and at least one spring assembly, connected between the at least two masses. Each spring assembly includes: at least two folded-shape springs, which are directly connected to each other at a connection point (i.e., a connection point is formed at a contact point between the two folded-shape springs); and at least two connection portions. The folded-shape springs are respectively connected to the masses through the connection portions, for operably driving the masses to move oppositely (e.g. simultaneously inward or outward) in a first direction. When the connection portions of the spring assembly move simultaneously inward or outward in the first direction, the connection point may move in a second direction which is perpendicular to the first direction.

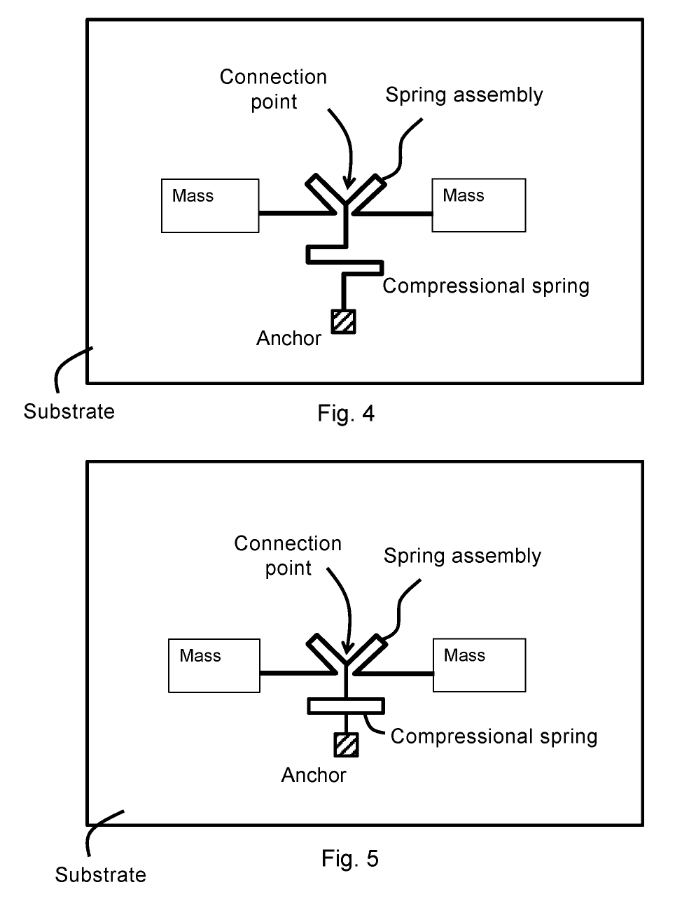

In one embodiment, each of the spring assemblies is directly or indirectly connected to a substrate through only one anchor (i.e., the number of the anchor corresponding to each spring assembly is exactly one, while there can be other components which are not anchors within the connection), and this will be explained in detail in the description of the embodiments of FIGS. 4, 5, 6, and 7. (The substrate is well known to those skilled in the art, so in some of the drawings the substrate is omitted for simplicity).

One feature of the MEMS device 20 according to the present invention is the two folded-shape springs in the spring assembly, wherein the two folded-shape springs are obliquely connected to each other. This oblique connection provides a motion relation between the connection point and the two connection portions as shown in FIG. 3. When the two connection portions move oppositely in the first direction, the connection point moves in the second direction which is perpendicular to the first direction. By such arrangement, when the at least two masses move oppositely in the first direction, the in-phase oscillation of the masses can be reduced or avoided. That is, the motion of one mass does not easily couple to another mass, so the in-phase oscillation can be greatly reduced.

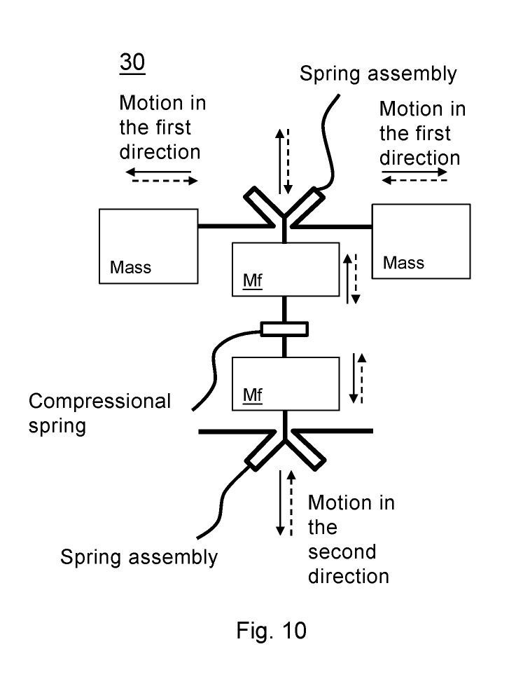

In one embodiment, it is arranged such that the motions in the first direction and the second direction correspond to each other. In the upper portion of FIG. 3, when the two connection portions move simultaneously outward in the first direction, the connection point correspondingly moves upward in the second direction. In the bottom portion of FIG. 3, when the two connection portions move simultaneously inward in the first direction, the connection point correspondingly moves downward in the second direction. Therefore, the motions of the two connection portions, and the motion of the connection point are synchronous to each other. In the MEMS device including two spring assemblies (FIG. 10, 11, 12, or 13), when the two connection portions move simultaneously inward in the first direction (motions in dashed lines), the two connection points correspondingly move inward in the second direction (motions in dashed lines); or, when the two connection portions move simultaneously outward in the first direction (motions in solid lines), the two connection points correspondingly move outward in the second direction (motions in solid lines).

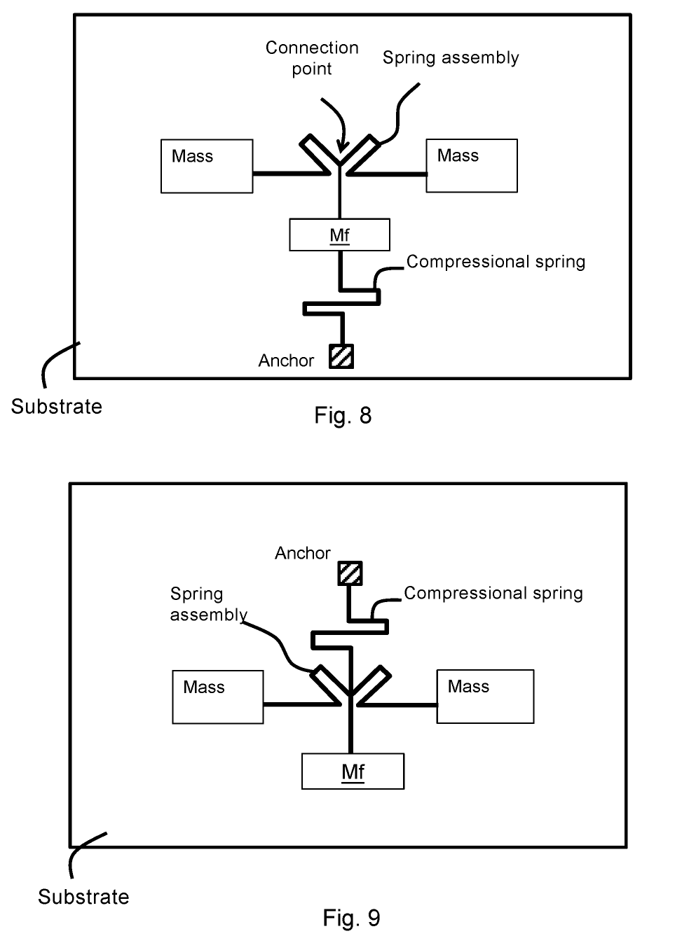

In FIG. 2 or 3, the motion of the masses in the first direction can be generated by various ways. In one embodiment, the motion of the masses in the first direction may be driven by a drive unit which is connected to the masses. Besides, each spring assembly may be directly connected to a compressional spring (FIG. 4, 5, 6, 7, or 9), or indirectly connected to a compressional spring (FIG. 8 or 10). In both the embodiments of FIGS. 8 and 10, the spring assembly is connected to the compressional spring through the at least one first internal mass Mf. Preferably, the compressional spring is directly or indirectly connected to the connection point between the folded-shape springs. When the compressional spring is directly or indirectly connected to the connection point, the motion of the two connection portions of the spring assembly is further restricted by the compressional spring so that the two connection portions are even less likely to generate in-phase oscillations. However, the compressional spring and the direct or indirect connection between the compressional spring and the connection point is preferred but not necessary. Embodiments wherein there is no compression spring or no connection between the compressional spring and the connection point are still within the spirit of the present invention.

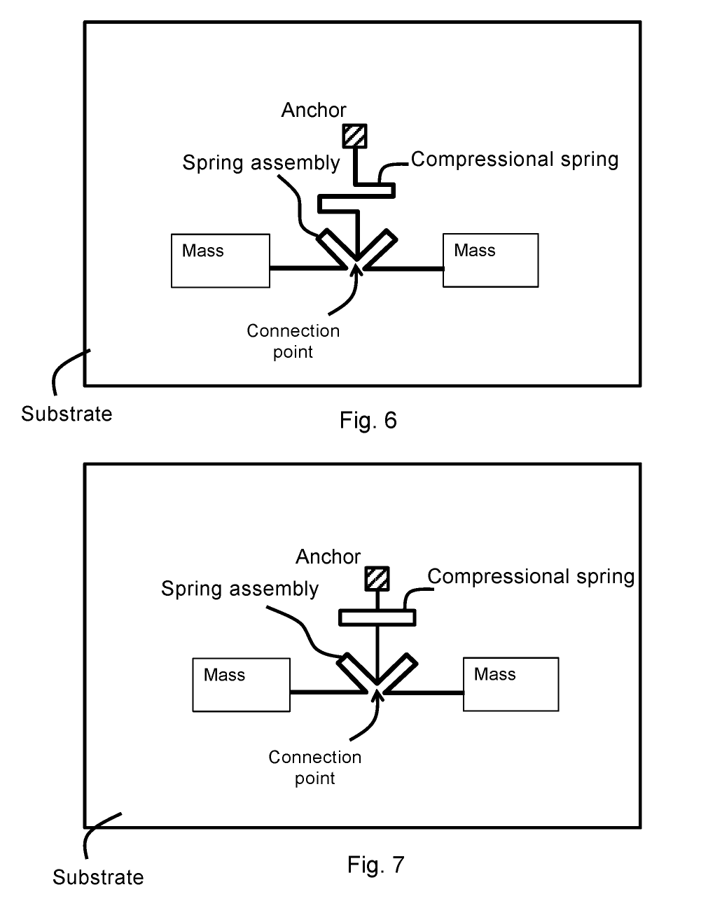

In the embodiments of FIG. 4, 5, 6, or 7, each spring assembly is connected to the substrate through only one anchor (i.e., the number of the anchor is one, but there can be other components which are not anchors). In these embodiments the connection point is connected to the compressional spring, wherein the compressional spring may be an S-shape compressional spring (FIG. 4 or 6), or a ring shape compressional spring (FIG. 5 or 7). According to the embodiments, the compressional spring may be located at an upper side of the connection point (FIG. 6 or 7), or the compressional spring may be located at a lower side of the connection point (FIG. 4 or 5). According to FIGS. 4, 5, 6, and 7, each of the compressional springs is connected to the one anchor. However, according to the present invention, the compressional spring is not necessarily required to be connected to the anchor. For example, in the embodiment of FIG. 10, the compressional spring is connected between two first internal masses Mf.

According to the present invention, besides the masses which move in the first direction, the MEMS device may further include one or more other internal masses, which move in a different direction from the first direction. In FIGS. 8 and 9, the connection point is connected to a first internal mass Mf. In FIG. 8, the connection point is connected to the compressional spring through the first internal mass Mf, wherein the compressional spring may be further connected to the anchor as shown in FIG. 8, or the compressional spring may be further connected to another first internal mass Mf as shown in FIG. 10; in FIG. 10, the compressional spring is connected between two first internal masses Mf. In FIG. 9, the connection point is directly connected to the compressional spring and the first internal mass Mf, and is connected between the compressional spring and the first internal mass Mf. In short, one can decide the connection design between the connection point and the compressional spring in various ways according to design requirements. In FIGS. 8 and 9, the first internal mass Mf can move in the second direction.

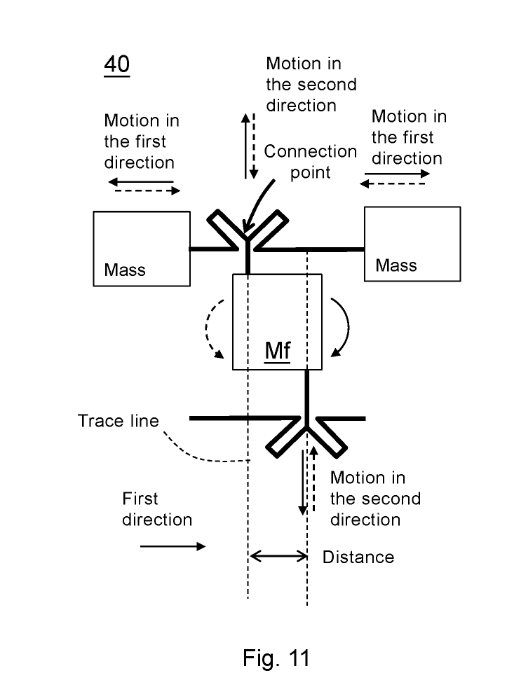

In the embodiments of FIGS. 10 and 11, the MEMS devices 10 and 11, include two spring assemblies and at least one first internal mass Mf. In FIG. 10, there are two first internal masses Mf between the two connection points of the two spring assemblies. In FIG. 11, there is one first internal mass Mf between the two connection points of the two spring assemblies. The at least one first internal mass Mf (for example, the two first internal masses Mf in FIG. 10) may be driven to move in the second direction; or the at least one first internal mass Mf (for example, the one first internal mass Mf in FIG. 11) may be driven to rotate. In FIG. 10, the layout of the two spring assemblies is mirror symmetric; however, the symmetric layout is preferred but not necessary. That is, the layout of the spring assemblies can be non-symmetric.

In FIG. 11, the upper side and the lower side of the first internal mass Mf are respectively connected to the two connection points of the two spring assemblies. The two connection points are separated by a distance in the first direction. When the two connection points move simultaneously inward or outward (motions in dashed lines or solid lines), the motions of the two connection points drive the first internal mass Mf to rotate as shown in the figure (rotations in dashed line or solid line). In detail, in FIG. 11, the two connection points of the two spring assemblies are separated by a distance in the first direction, and they move in two trace lines which are in parallel to each other by the distance. As the upper side and the lower side of the first internal mass Mf are respectively connected to the two connection points which move according to the two trace lines, the first internal mass Mf rotates (in dashed line or solid line).

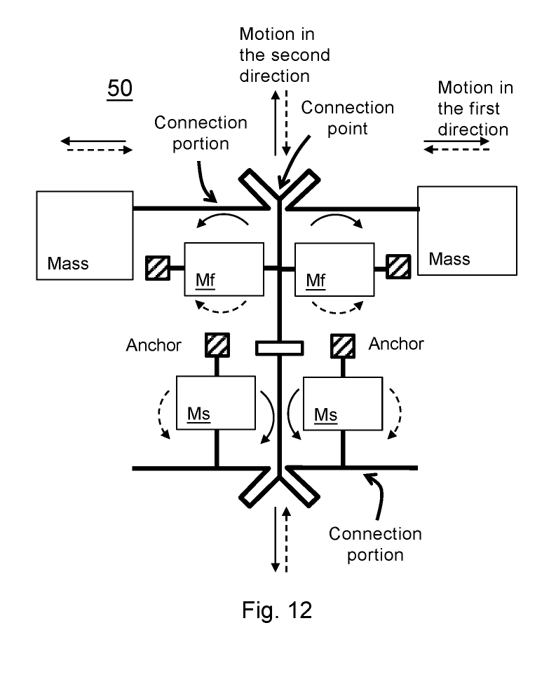

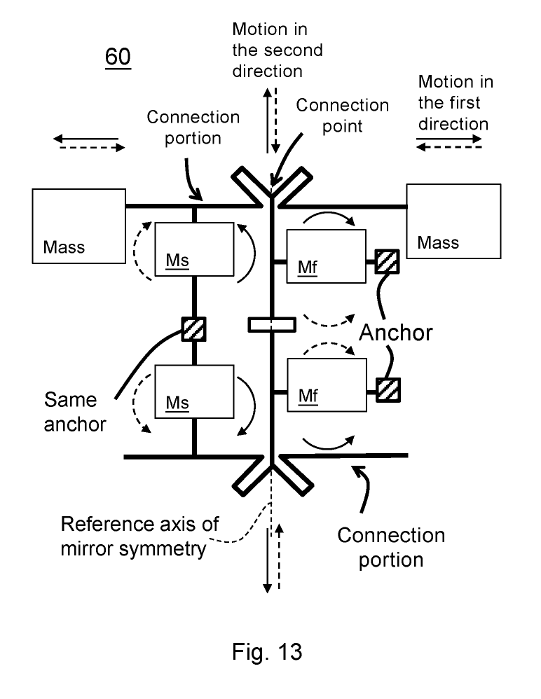

As shown in FIGS. 10, 12, and 13, each of the MEMS devices 30, 50, and 60 includes two first internal masses Mf, which are connected to the at least one connection point (the two first internal masses Mf in FIGS. 10 and 13 are respectively connected to the two connection points at opposite sides of the compressional spring, and the two first internal masses Mf in FIG. 12 are both connected between the same connection point and the compressional spring). In the embodiment of FIG. 10, the first internal masses Mf are connected to each other through the compressional spring; one side of each of the first internal masses Mf is connected to the compressional spring and another side of each of the first internal masses Mf is connected to the corresponding connection point. The two spring assemblies are configured to operably drive the two first internal masses Mf move simultaneously outward (motions in solid lines) or inward (motions in dashed lines) in the second direction. In the embodiment of FIG. 12, one side of each of the two first internal masses Mf is connected to the same connection point, and another side of each of the two first internal masses Mf is connected to a corresponding anchor, wherein the two spring assemblies are configured to operably drive the two first internal masses Mf to rotate simultaneously in opposite directions (rotations shown in solid lines and dashed lines). In the embodiment of FIG. 13, two sides of the two first internal masses Mf are respectively connected to the two connection points (through corresponding compressional springs), and another side of each of the two first internal masses Mf is connected to a corresponding anchor, wherein the two spring assemblies are configured to operably drive the two first internal masses Mf to rotate simultaneously in opposite directions (rotations in solid lines and dashed lines). Note that the motions in the solid and dashed lines of the first internal masses Mf (in FIGS. 10, 12, and 13), respectively correspond to the two motions of the connection points in the solid and dashed lines in the second direction.

The layout of the first internal masses Mf can be modified according to design requirements. For example, in one embodiment, as shown in FIG. 12, the layout of the at least two first internal masses Mf are mirror symmetric at two opposite sides of the compressional spring (i.e., the compressional spring being on a reference axis of mirror symmetry). In another embodiment, as shown in FIG. 13, the two first internal masses Mf are at the same side of the compressional spring.

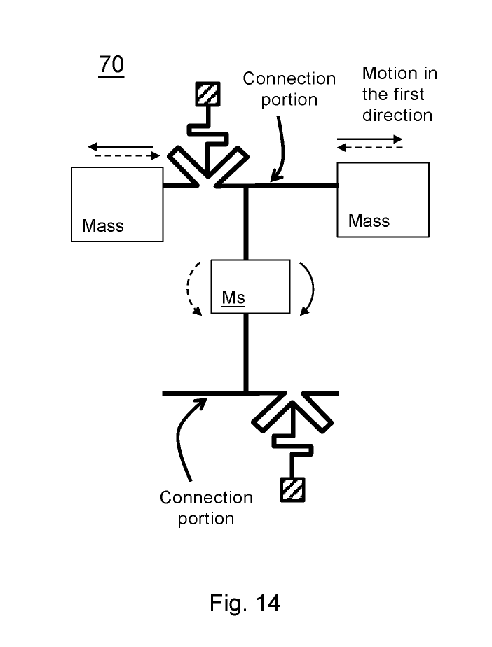

In the embodiments of FIGS. 12, 13, and 14, each of the MEMS devices 50, 60, and 70 further includes at least one second internal mass, Ms, which is connected to the corresponding connection portion. In the embodiment of FIG. 12, the two second internal masses Ms are respectively connected to the two connection portions of one same spring assembly, and another side of each of the two second internal masses Ms is connected to a corresponding anchor. In the embodiment of FIG. 13, the two second internal masses Ms are respectively connected to the connection portions of different spring assemblies, and the sides opposite to the sides connected to the two connection portions could be connected to the same anchor in the embodiment. In the embodiment of FIG. 14, the one second internal mass Ms is connected to the connection portions of different spring assemblies. In the MEMS devices 50, 60, and 70, the spring assemblies are configured to operably drive the at least one second internal mass Ms to rotate. Note that the motions in the solid and dashed lines of the at least one second internal mass (FIGS. 12, 13, and 14), respectively correspond to the two motions of the connection points in the solid and dashed lines in the second direction.

The aforementioned motion relations among the masses, the first internal masses, and the second internal masses, can be applied to, for example but not limited to, constructing a tuning fork MEMS device. In one embodiment of the present invention, the tuning fork MEMS device of the present invention may include a tuning fork gyroscope. The MEMS device of the present invention can generate motions in multiple directions, and these motions in different directions can be used for sensing a Coriolis force, to sense angular velocities in multiple dimensions.

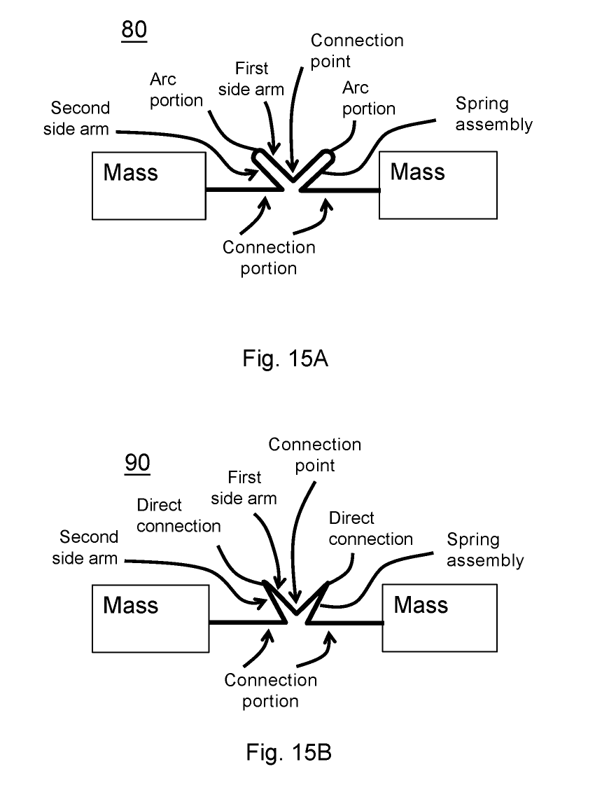

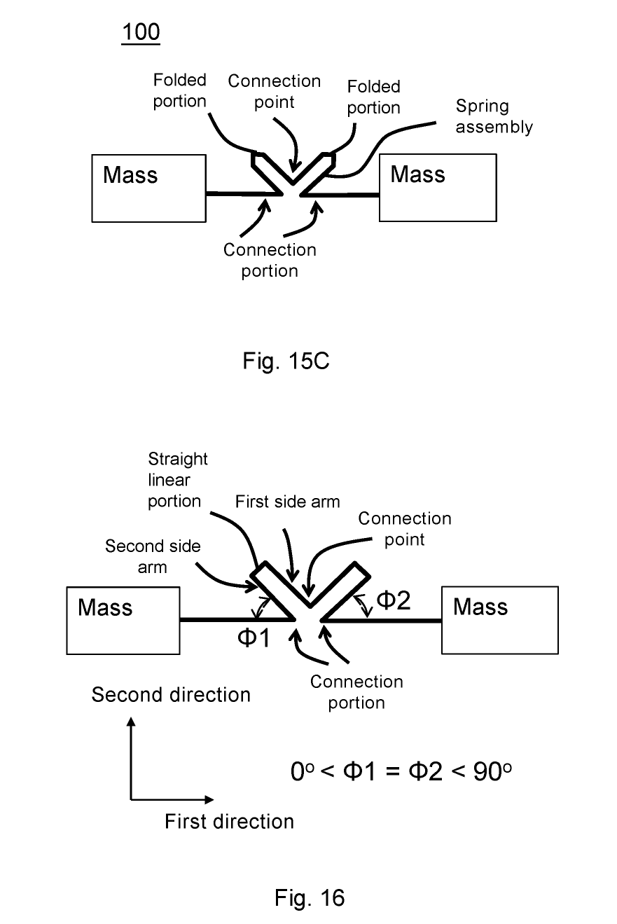

The embodiments of FIGS. 15A-15C illustrate that the folded-shape springs in the spring assemblies may include different kinds of shape designs. According to the present invention, each of the folded-shape springs may include a first side arm and a second side arm (FIG. 16), which are respectively connected to the connection point and the connection portion, wherein the first side arm and the second side arm may be connected to each other (1) directly (the MEMS structure 90 of FIG. 15B); (2) by a straight linear portion between the first side arm and the second side arm (FIGS. 2 and 16); (3) by an arc portion between the first side arm and the second side arm (the MEMS structure 80 of FIG. 15A); or (4) by a folded portion between the first side arm and the second side arm (the MEMS structure 100 of FIG. 15C). To sum up, the folded-shape spring may have different kinds of shape designs as long as it has a folded-shape to provide a resilient force.

In the embodiment of FIG. 16, each of the folded-shape springs includes the first side arm and the second side arm which are connected to the connection point and the connection portion respectively, and there are two angles Φ1 and Φ2 between the two second side arms and the corresponding connection portions. The angles Φ1 and Φ2 are in a range between 0 and 90 degrees. In one embodiment, the ranges of the angles Φ1 and Φ2 may be changed according to the design requirement. For example, the ranges of the angles Φ1 and Φ2 are between a first angle and a second angle. The first angle may be e.g. 0 degree, 5 degrees, 10 degrees, 15 degrees, 20 degrees, 25 degrees, 30 degrees, 35 degrees, 40 degrees, etc. The second angle may be e.g. 85 degrees, 80 degrees, 75 degrees, 70 degrees, 65 degrees, 60 degrees, 55 degrees, etc. One may decide a preferred combination of the first and second angles according to the design requirement. Referring to FIG. 16 and the embodiment of FIG. 3, when the spring assembly drives the masses to move simultaneously outward in the first direction, the angles Φ1 and Φ2 increase. When the spring assembly drives the masses to move simultaneously inward in the first direction, the angles Φ1 and Φ2 decrease. In one embodiment, the angles Φ1 and Φ2 are substantially equal to each other.

In one embodiment, the first side arm and the second side arm may be parallel to each other (FIG. 15A). In another embodiment of FIG. 15B, the first side arm and the second side arm are not parallel to each other. The relation between the first side arm and the second side arm can be determined according to the design requirement.

In one embodiment, the folded-shape springs of the spring assembly are respectively connected to the at least two masses through the corresponding connection portions, wherein the connection point of the spring assembly is directly or indirectly connected to the compressional spring, or the connection point is connected to the first internal mass. The connection between the connection points and the compressional spring, or the connection between the connection points and the first internal mass, can prevent the at least two masses from having an in-phase oscillation in the first direction.

In comparison with U.S. Pat. No. 9,127,943, the present invention provides a MEMS device capable of reducing the in-phase oscillation to increase the sensing sensitivity.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention; for example, there may be additional devices or structures inserted between two structures shown to be indirect connection in the embodiments, as long as such inserted devices or structures do not affect the primary function of the MEMS device. All such modifications and variations should fall in the scope of the present invention. Besides, an embodiment or a claim of the present invention does not need to attain or include all the objectives, advantages or features described in the above. The abstract and the title are provided for assisting searches and not to be read as limitations to the scope of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment.

What is claimed is:

1. A MEMS device, comprising:
at least two masses; and
at least one spring assembly, connected between the masses, each of the spring assemblies including:
at least two folded-shape springs, directly connected to each other at a connection point; and
at least two connection portions, wherein the folded-shape springs are respectively connected to the masses through the connection portions, for operably driving the masses to move oppositely in a first direction.

2. The MEMS device of claim 1, wherein each of the spring assemblies is connected to a substrate through one anchor, and there is exactly one anchor between each spring assembly and the substrate.

3. The MEMS device of claim 2, wherein the one anchor is connected to the connection point through a compressional spring, for driving the connection point to move in a second direction which is perpendicular to the first direction, wherein the connection point and the compressional spring are directly or indirectly connected to each other.

4. The MEMS device of claim 3, wherein the connection point is connected to the compressional spring through a first internal mass.

5. The MEMS device of claim 3, wherein the connection point is directly connected to a first internal mass.

6. The MEMS device of claim 1, wherein the MEMS device comprises at least two spring assemblies, and the at least two masses are connected to each other through the at least two spring assemblies, wherein a layout of the at least two spring assemblies is mirror symmetric.

7. The MEMS device of claim 6, further comprising: at least one first internal mass, connected between the connection points of the spring assemblies, wherein the spring assemblies are configured to operably drive the at least one first internal mass to move in a second direction which is perpendicular to the first direction, or to operably drive the at least one first internal mass to rotate.

8. The MEMS device of claim 7, wherein the connection points of the spring assemblies are separated by a distance in the first direction, such that the spring assemblies are configured to operably drive the at least one first internal mass to rotate.

9. The MEMS device of claim 6, further comprising at least two first internal masses, connected to each other through a compressional spring which is connected to one side of each of the first internal masses, and each of the first internal masses further includes another side connected to a corresponding one of the connection points, whereby the spring assemblies are configured to operably drive the at least two first internal mass to move oppositely in a second direction, which is perpendicular to the first direction.

10. The MEMS device of claim 6, further comprising at least two first internal masses, which are connected to each other through a compressional spring which is connected to one side of each of the first internal masses, and the first internal masses are connected to a corresponding one of the connection points through the compressional spring, and each of the first internal masses further includes another side connected to a corresponding anchor, wherein the spring assemblies are configured to operably drive the at least two first internal masses to rotate in opposite directions.

11. The MEMS device of claim 10, wherein the at least two first internal masses are mirror-symmetrically located at opposite sides of the compressional spring, or are located at the same side of the compressional spring.

12. The MEMS device of claim 1, wherein the MEMS device comprises two spring assemblies and at least one second internal mass, and the at least one second internal mass is connected to the connection points, wherein the spring assemblies are configured to operably drive the at least one second internal mass to rotate.

13. The MEMS device of claim 12, wherein the MEMS device comprises two second internal masses, each of the second internal masses including one side connected to a corresponding one of the connection portions, and another side connected to an anchor, wherein the two spring assemblies are configured to operably drive the second internal masses to rotate in opposite directions.

14. The MEMS device of claim 12, wherein the MEMS device comprises two second internal masses, each of the second internal masses including one side connected to a corresponding one of the connection portions, and another side connected to a same anchor, wherein the two spring assemblies are configured to operably drive the second internal masses to rotate in opposite directions.

15. The MEMS device of claim 3, wherein when the connection portions move simultaneously outward in the first direction, the connection point correspondingly moves outward in the second direction; or when the connection portions move simultaneously inward in the first direction, the connection point correspondingly moves inward in the second direction.

16. The MEMS device of claim 1, wherein each of the folded-shape springs includes a first side arm and a second side arm, which are respectively connected to the connection point and the connection portion, wherein the first side arm and the second side arm are connected to each other (1) directly; (2) by a straight linear portion between the first side arm and the second side arm; (3) by an arc portion between the first side arm and the second side arm; or (4) by a folded portion between the first side arm and the second side arm.

17. The MEMS device of claim 1, wherein each of the folded-shape springs includes a first side arm and a second side arm, which are respectively connected to the connection point and the connection portion, wherein an angle between the second side arm and the corresponding connection portion nearest to this second side arm is between 0 and 90 degrees.

18. The MEMS device of claim 17, wherein when the spring assemblies drive the masses to move outward in the first direction, the angle increases; or when the spring assemblies drive the masses to move inward in the first direction, the angle decreases.

19. The MEMS device of claim 1, wherein the MEMS device comprises a tuning fork MEMS structure.

20. The MEMS device of claim 1, wherein the MEMS device comprises a tuning fork gyroscope.
